(19) United States
(12) Patent Application Publication
(10) Pub. No.: US 2012/0025203 A1
(43) Pub. Date: Feb. 2, 2012

(54) SEMICONDUCTOR DEVICE

(75) Inventors: Ken Nakata, Kanagawa (JP); Isao Makabe, Kanagawa (JP); Keiichi Yui, Kanagawa (JP)

(73) Assignee: SUMITOMO ELECTRIC INDUSTRIES, LTD., Osaka (JP)

(21) Appl. No.: 13/194,396

(22) Filed: Jul. 29, 2011

(30) Foreign Application Priority Data
Jul. 29, 2010 (JP) 2010-171067

(51) Int. Cl. H01L 29/22

(52) U.S. Cl. 257/76; 257/E29.089

(57) ABSTRACT

A semiconductor device includes a first GaN layer formed on a substrate, the first GaN layer including a transition metal and an impurity under constant concentration, the impurity forming a deeper energy level in the first GaN layer than energy level formed by the transition metal, a second GaN layer formed on the first GaN layer, the second GaN layer including the transition metal and the impurity under inclined concentration, an inclined direction of the transition metal being same as an inclined direction of the impurity, and an electron supply layer formed on the second GaN layer.

### CROSS-REFERENCE TO RELATED APPLICATION

This application is based upon and claims the benefit of priority of the prior Japanese Patent Application No. 2010-171067 filed on Jul. 29, 2010, the entire contents of which are incorporated herein by reference.

### BACKGROUND

(i) Technical Field

A certain aspect of the embodiments discussed herein is related to a semiconductor device. Another aspect of the embodiments is related to a semiconductor device having a GaN layer including a transition metal.

(ii) Related Art

A semiconductor devices using a nitride semiconductor is used as a power device operating at high frequencies and outputting high power. Particularly, there is known an FET such as a high electron mobility transistor (HEMT) as a semiconductor device suitable for amplification in a high-frequency or RF (radio Frequency) band such as a microwave band, a quasi-millimeter band or a millimeter band.

As a semiconductor device having a nitride semiconductor, there is known a semiconductor device in which an AlN layer, an AlGaN layer, a GaN layer and an electron supply layer are sequentially stacked in this order on a Si substrate (see Japanese Patent application Publication No. 2008-166349). As a substrate for the semiconductor device including a nitride semiconductor, there is known a SiC substrate having a lattice constant relatively close to that of GaN besides the Si substrate. It is also known to add a transition metal to the GaN layer of the semiconductor device having the nitride semiconductor to obtain a larger resistance. Thus, improvements in the characteristics of the device are expected. For example, leakage current may be suppressed, or the pinch-off characteristic may be improved.

However, energy level of Fe doped GaN is unstable due to energy level instability of Fe. An electron device using such unstable GaN has unstable pinch-off characteristic.

### SUMMARY

According to an aspect of the present invention, there is provided a semiconductor device including: a first GaN layer formed on a substrate, the first GaN layer including a transition metal and an impurity under constant concentration, the impurity forming a deeper energy level in the first GaN layer than energy level formed by the transition metal; a second GaN layer formed on the first GaN layer, the second GaN layer including the transition metal and the impurity under inclined concentration, an inclined direction of the transition metal being same as an inclined direction of the impurity; and an electron supply layer formed on the second GaN layer.

### BRIEF DESCRIPTION OF THE DRAWINGS

FIG. 1 is a schematic cross-sectional view of an epitaxial layer of a semiconductor device in accordance with a comparative example 1;

FIG. 2 is a schematic view of the Fe concentration associated with the depth from the upper surface of an AlGaN electron supply layer;

FIG. 3 is a schematic view of energy levels of Fe added to an Fe-GaN layer;

FIG. 4 is a schematic view that describes a problem about addition of C;

FIG. 5 is a schematic cross-sectional view of an epitaxial layer of a semiconductor device in accordance with a first embodiment;

FIG. 6 is a schematic view of the Fe concentration and the C concentration associated with the depth from the upper surface of an AlGaN electron supply layer of the semiconductor device in accordance with the first embodiment;

FIG. 7 is a schematic view of the energy levels of Fe and the energy level of C added to a first GaN layer of the semiconductor device in accordance with the first embodiment; and

FIG. 8 is a schematic cross-sectional view of another semiconductor device in accordance with the first embodiment.

### DETAILED DESCRIPTION

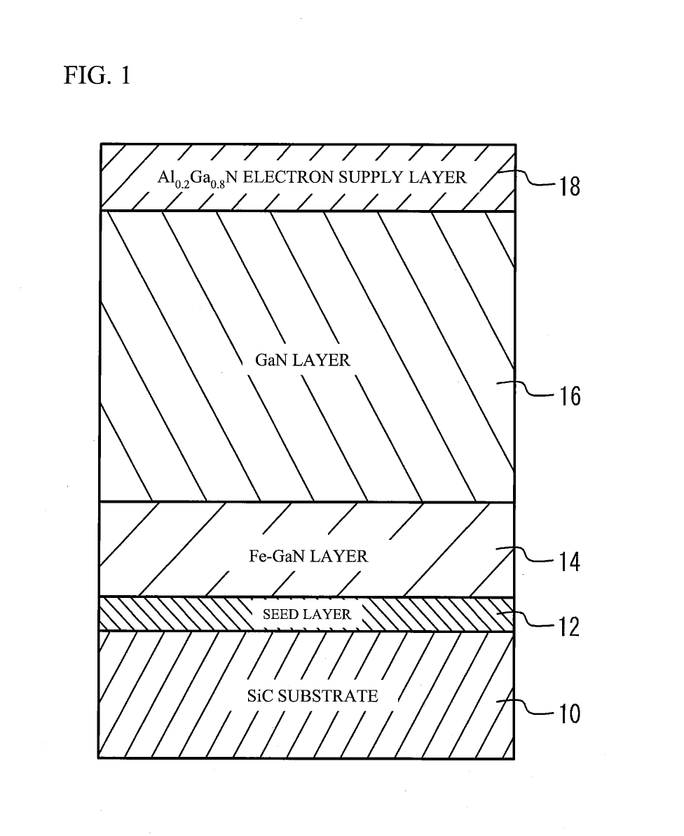

First, a semiconductor device in accordance with a comparative example 1 is described. FIG. 1 is a schematic cross-sectional view of an epitaxial layer of a semiconductor device in accordance with the comparative example 1. As illustrated in FIG. 1, a seed layer 12 made of aluminum nitride (AlN) is grown on a SiC substrate 10 by metal organic chemical vapor deposition (MOCVD), for example. The growth condition is as follows.

Source gas: TMA (trimethylaluminium), NH₃ (ammonia)

Growth temperature: 1100° C.

Pressure: 13.3 kPa

Thickness: 25 nm

An Fe-GaN layer 14 is grown on the seed layer 12 under the following condition.

Source gas: TMG (trimethylgallium), NH₃

Growth temperature: 1050° C.

Pressure: 13.3 kPa

V/III ratio: 1000

Growth rate: 0.3 nm/sec

Doping: doped with Fe at 1.0×10¹⁶ cm⁻³

Thickness: 200 nm

A GaN layer 16 is grown on the Fe-GaN layer 14 under the following condition.

Source gas: TMG, NH₃

Growth temperature: 1100° C.

Pressure: 13.3 kPa

V/III ratio: 5000

Growth rate: 0.2 nm/sec

Thickness: 1500 nm

An AlGaN electron supply layer 18 is grown on the GaN layer 16 under the following condition.

Source gas: TMA, TMG, NH₃

Al composition ratio: 20%

Thickness: 25 nm

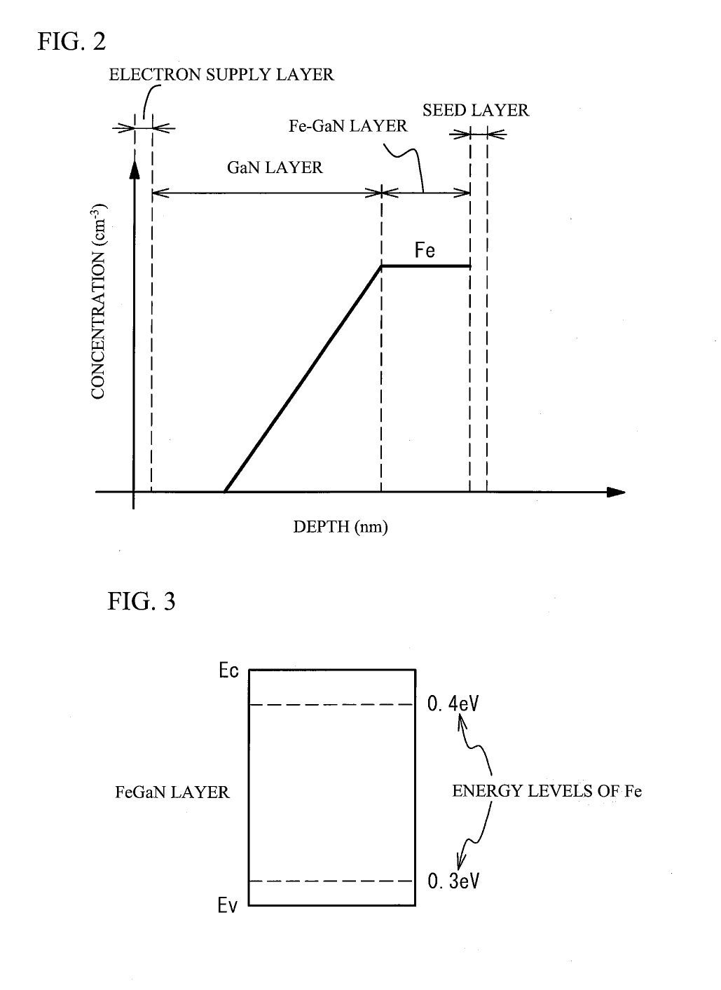

FIG. 2 is a schematic view of the Fe concentration associated with the depth from the upper surface of the AlGaN electron supply layer 18. As illustrated in FIG. 2, Fe is included not only in the Fe-GaN layer 14 but also in the GaN layer 16 in which the Fe concentration decreases gradually towards the AlGaN electron supply layer 18 from the interface with the Fe-GaN layer 14. It is conceivable that the reason why Fe is included in the GaN layer 16 is as follows. The transition metal such as Fe is used as a dopant in the form of ferricyan compound. Even if a supply of the ferricyan compound to the MOCVD chamber is stopped, the ferricyan compound remains on the growth plane of the Fe-GaN layer 14 for a long time. The remaining ferricyan compound is included in the GaN layer 16 so as to have a concentration profile as illustrated in FIG. 2.

FIG. 3 is a schematic view of the energy level of Fe added to the Fe-GaN layer 14. Fe may form varying energy levels in vicinity of two energy levels described in FIG. 3. The two energy levels are close to the energy level Ec of the conduction band of GaN and the energy level Ev of the valence band of GaN. Thus, the energy levels (Ec-Ef) of Fe doped GaN layer tends to be unstable. In order to stabilize the energy levels of Fe, it is conceivable that an impurity having a deeper energy level than that of Fe is further added to the Fe-GaN layer 14.

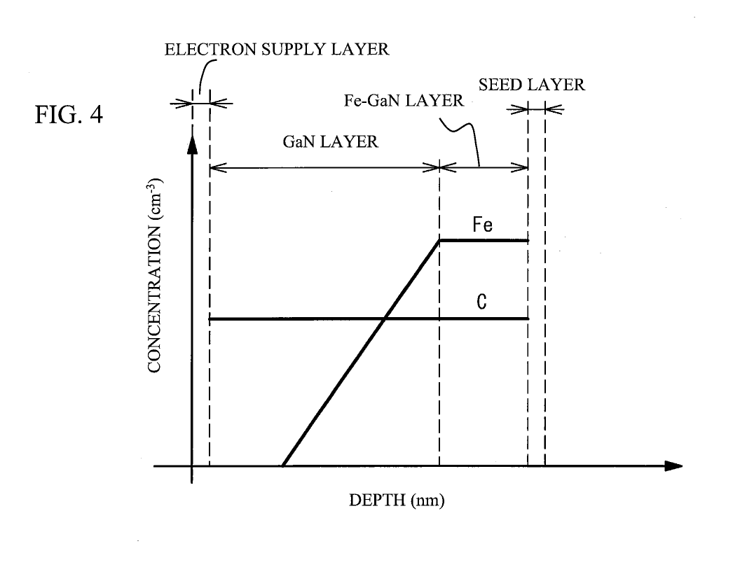

For example, carbon (C) may be an impurity having a deeper energy level than that of Fe. However, as illustrated in FIG. 2, Fe is included in the GaN layer 16 so that the Fe concentration decreases gradually from the interface with the Fe-GaN layer 14. Thus, the addition of C to only the Fe-GaN layer 14 does not stabilize the energy levels greatly. Taking the above into consideration, as illustrated in FIG. 4, it is conceivable that C is added to not only Fe-GaN layer 14 but also the GaN layer 16 at a fixed concentration. However, C itself functions as a trap. As the number of traps increases, the transient characteristic of the current-voltage characteristic, which may be typically current collapse, may be degraded. Thus, it is not preferable that C is excessively added.

According to an aspect of embodiments described below, the energy levels of Fe may be stabilized without excessively increasing the number of traps.

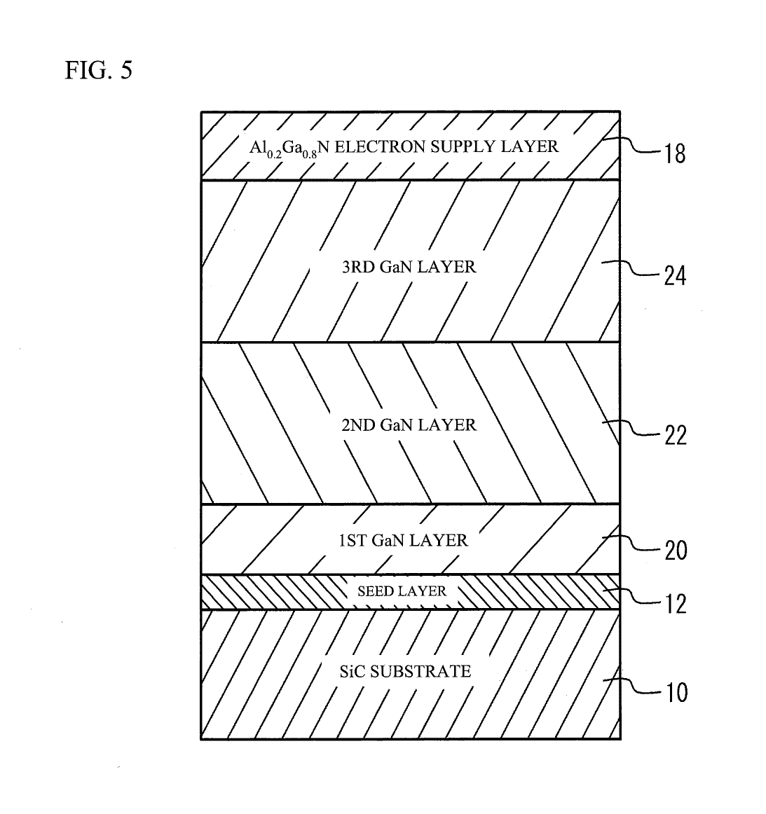

FIG. 5 is a schematic cross-sectional view of an epitaxial layer of a semiconductor device in accordance with a first embodiment. Referring to FIG. 5, the surfaces of the SiC substrate 10 after acid cleaning is cleaned in an H₂ atmosphere at a temperature higher than the growth temperature. Next, the seed layer 12 made of AlN is grown on the SiC substrate 10 by MOCVD under the following condition.

Source gas: TMA, NH₃

Growth temperature: 1100° C.

Pressure: 13.3 kPa

Thickness: 25 nm

A first GaN layer 20 including Fe is grown on the seed layer 12 under the following condition.

Source gas: TMG, NH₃

Growth temperature: 1050° C.

Pressure: 13.3 kPa

V/III ratio: 1000

Growth rate: 0.3 nm/sec

Doping: doped with Fe at 1.0×10¹⁶ cm⁻³

Thickness: 200 nm

A second GaN layer 22 is grown on the first GaN layer 20 under the following condition.

Source gas: TMG, NH₃

Growth temperature: gradually increase from 1050° C. to 1100° C.

Pressure: 13.3 kPa

V/III ratio: 1000

Growth rate: 0.3 nm/sec

Thickness: 600 nm

A third GaN layer 24 is grown on the second GaN layer 22 under the following condition.

Source gas: TMG, NH₃

Growth temperature: 1100° C.

Pressure: 13.3 kPa

V/III ratio: 5000

Growth rate: 0.2 nm/sec

Thickness: 600 nm

The AlGaN electron supply layer 18 is grown on the third GaN layer 24 under the following condition.

Source gas: TMA, TMG, NH₃

Al composition ratio: 20%

Thickness: 25 nm

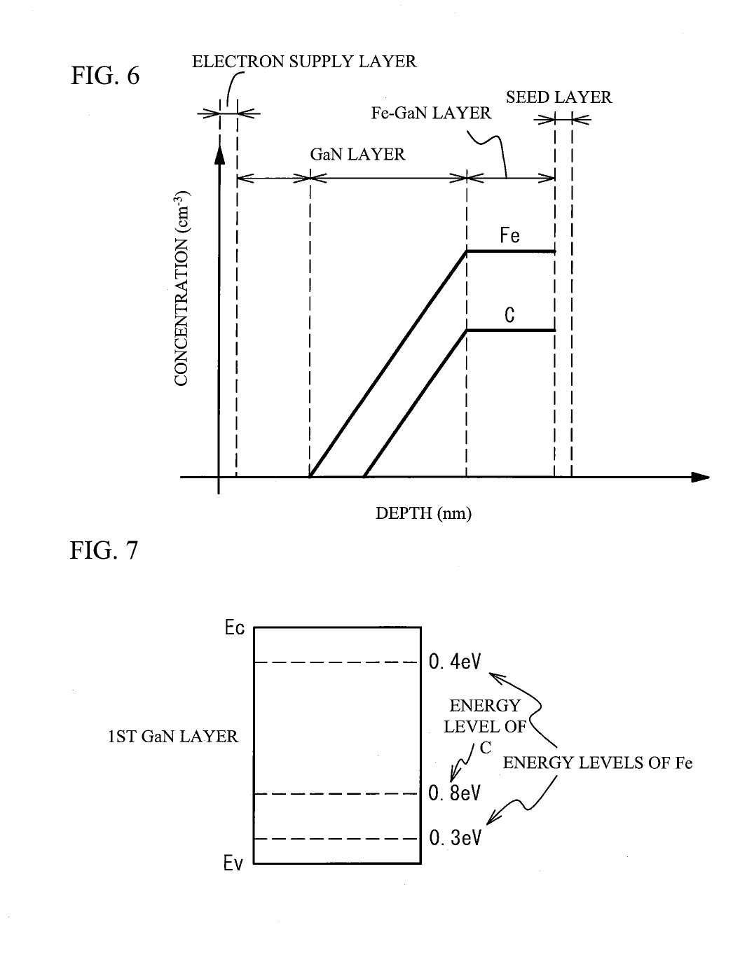

FIG. 6 is a schematic view of the Fe concentration and the C concentration associated with the depth from the upper surface of the AlGaN electron supply layer 18. As illustrated in FIG. 6, Fe is included in the first GaN layer 20 at a fixed concentration and is further included in the second GaN layer 22 at a gradually decreasing concentration towards the third GaN layer 24. This is because of the reason previously described with reference to FIG. 2. C is included in the first GaN layer 20 at a concentration lower than that of Fe included in the first GaN layer 20. C is further included in the second GaN layer 22 so as to follow a change of the Fe concentration in the second GaN layer 22. The C concentration in the second GaN layer 22 is lower than the Fe concentration therein.

The reason why C is included in the first GaN layer 20 at a high fixed concentration is that the first GaN layer 20 is grown at a temperature that is relatively as low as 1050° C. with a V/III ratio that is relatively as low as 1000 and with a growth rate that is relatively as fast as 0.3 nm/sec. In the growth of GaN by MOCVD with TMG and NH₃ being used as a source, C included in the source is considerably included in growing GaN. A larger amount of C may be included in GaN by setting the growth temperature and the V/III ratio to relatively low levels and setting the growth rate to a relatively high level as described above.

Similarly, the C concentration in the second GaN layer 22 changes. This is because the growth temperature is changed from 1050° C. to 1100° C. By appropriately adjusting the increasing rate of the growth temperature, the C concentration can be changed so as to follow the change of the Fe concentration, as illustrated in FIG. 6. That is, the change rate of the C concentration can be matched with that of the Fe concentration.

FIG. 7 is a schematic view of the energy levels of Fe and C doped first GaN layer 20 and the second GaN layer 22. Referring to FIG. 7, Fe forms energy levels in GaN at vicinity of 0.4 eV from Ec and vicinity of 0.3 eV from Ev, and the energy level of C is formed at 0.8 eV from Ev of GaN. Since the energy level formed by C is deeper than the energy levels formed by Fe, the energy levels of Fe doped GaN can be stabilized.

As described above, the semiconductor device of the first embodiment includes the first GaN layer 20 including Fe and C and the second GaN layer 22 having the C concentration that changes so as to follow the change of the Fe concentration, in which Fe is a transition metal and C is a deeper energy level than the energy levels of Fe. Thus, as has been described with reference to FIG. 7, the energy level deeper than the energy levels of Fe is formed by C, so that the energy levels of Fe can be stabilized. Since the C concentration is changed so as to follow the change of the Fe concentration in the second GaN layer 22, it is possible to suppress degradation of the transient response of the current-voltage characteristic such as current collapse due to the traps without too many C atoms.

As depicted in FIG. 6, it is preferable that the C concentration is lower than that of Fe. A high C concentration leads to the presence of many C atoms, which affect the transient characteristic. In contrast, an excessively low C concentration weakens the effect of stabilizing the energy levels of Fe. Thus, the C concentration in the first GaN layer 20 is preferably 1.0×10¹⁴/cm³ to 1.0×10¹⁶/cm³, and is more preferably 1.0×10¹⁵/cm³ to 5.0×10¹⁵/cm³.

As illustrated in FIG. 6, it is preferable that the difference between the Fe concentration and he C concentration in the second GaN layer 22 is constant. It is thus preferable that the change rate of the Fe concentration and that of the C concentration are equal to each other. It is thus possible to stabilize the energy levels of Fe more reliably.

The Fe concentration of the second GaN layer 22 that gradually decreases from the interface with the first GaN layer 20 as illustrated in FIG. 5 may become zero at a position that is approximately 200 nm or less away from the upper surface of the first GaN layer 20. Thus, the second GaN layer 22 having the C concentration that changes so as to follow the change of the Fe concentration may be approximately 600 nm thick. The third GaN layer 24 having a low constant C concentration is provided between the second GaN layer 22 and the AlGaN electron supply layer 18. Due to the presence of the third GaN layer 24 having a low C concentration, it is possible to reduce broad emission in a wavelength range of 500 nm to 700 nm (yellow band).

THE TRANSITION METAL INCLUDED IN THE FIRST GAN LAYER 20 OF THE FIRST EMBODIMENT IS NOT LIMITED TO FE BUT MAY BE TITANIUM (TI), VANADIUM (V), CHROMIUM (CR), MANGANESE (MN), COBALT (CO), NICKEL (NI), OR COPPER (CU). It is particularly preferable to use a transitional fetal having two energy levels such as Fe. The substrate is not limited to SiC but may be a Si substrate, a sapphire substrate or the like.

The impurity having an energy level deeper than the energy level or levels of the transition metal is not limited to C but may be another impurity. Particularly, when the transition metal has two energy levels, it is preferable to use an impurity having an energy level between the two energy levels of the transition metal. As has been described with reference to FIG. 5, the C concentrations in the first GaN layer 20 and the second GaN layer 22 may be adjusted by controlling the growth condition. Thus, it is preferable that the impurity having an energy level deeper than the energy level or levels of the transition metal is C. The C concentrations in the first GaN layer 20 and the second GaN layer 22 may be adjusted by changing at least one of the growth temperature, the V/III ratio, and the growth rate.

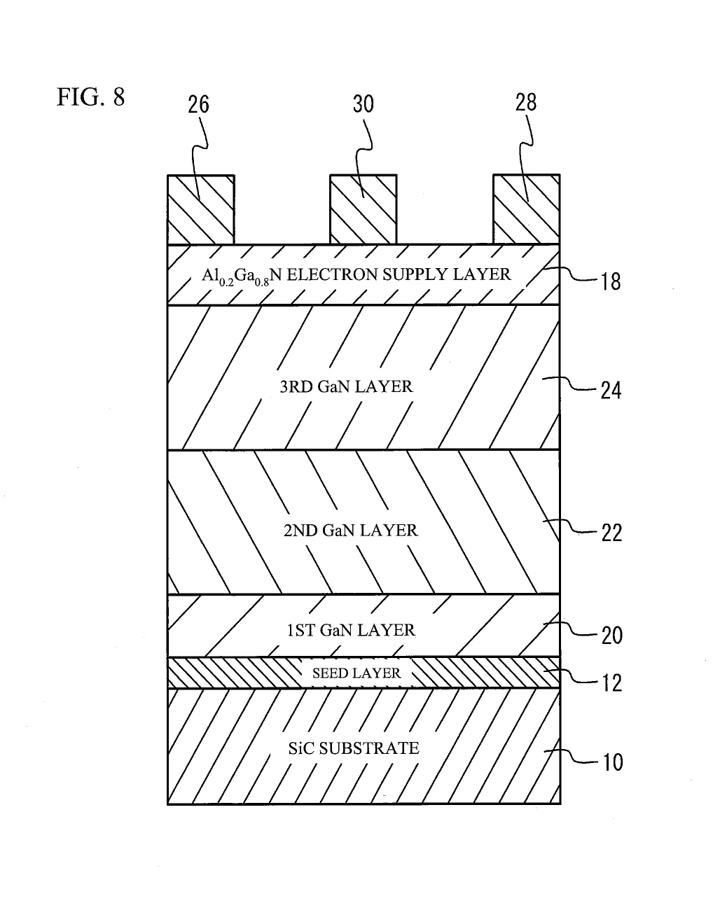

FIG. 8 is a schematic cross-sectional view of a semiconductor device in accordance with the first embodiment. Referring to FIG. 8, a source electrode 26 and a drain electrode 28, which are ohmic electrodes, are provided on the epitaxial layer described with reference to FIG. 5. The source electrode 26 and the drain electrode 28 have a two-layer structure composed of Ti and Al stacked in this order so that Ti contacts the AlGaN electron supply layer 18. A gate electrode 30 is provided on the AlGaN electron supply layer 18 and is interposed between the source electrode 26 and the drain electrode 28. The gate electrode 30 may be a two-layer structure composed of Ni and Au stacked in this order so that Ni contacts the AlGaN electron supply layer 18.

The electron supply layer is not limited to AlGaN but may be another material having a band gap greater than that of GaN.

The present invention is not limited to the specifically disclosed embodiments but may include various embodiments and variations within the scope of the claimed invention.

What is claimed is:

1. A semiconductor device comprising:
a first GaN layer formed on a substrate, the first GaN layer including a transition metal and an impurity under constant concentration, the impurity forming a deeper energy level in the first GaN layer than energy level formed by the transition metal;
a second GaN layer formed on the first GaN layer, the second GaN layer including the transition metal and the impurity under inclined concentration, an inclined direction of the transition metal being same as an inclined direction of the impurity; and
an electron supply layer formed on the second GaN layer.

2. The semiconductor device according to claim 1, wherein the concentration of the impurity is lower than that of the transition metal.

3. The semiconductor device according to claim 1, wherein an inclining rate of the transition metal is same as an inclining rate of the impurity.

4. The semiconductor device according to claim 1, further comprising a third GaN layer that is provided between the second GaN layer and the electron supply layer and has a constant concentration of the impurity.

5. The semiconductor device according to claim 1, wherein the transition metal is forming energy levels in vicinity of two separated energy levels in the first and second GaN layer.

6. The semiconductor device according to claim 5, wherein the impurity forms energy level between the two separated energy levels of the transition metal.

7. The semiconductor device according to claim 1, wherein the transition metal is Fe.

8. The semiconductor device according to claim 1, wherein the impurity is C.

9. The semiconductor device according to claim 1, wherein the electron supply layer has band a gap greater than the second GaN layer.

10. The semiconductor device according to claim 1, wherein the electron supply layer is AlGaN.

11. The semiconductor device according to claim 1, further comprising a source electrode, a drain electrode and a gate electrode are formed on the electron supply layer.

12. A semiconductor device comprising:
a first GaN layer formed on a substrate, the first GaN layer is doped with Fe and C under a constant concentration;
a second GaN layer formed on the first GaN layer, the second GaN layer having an upper face and a lower face, the second GaN layer is doped with Fe and C, a doping concentration of Fe and C being decreasing toward the upper face; and
an electron supply layer formed on the upper face of the second GaN layer.

13. The semiconductor device according to claim 12, wherein a doping concentration of C is lower than a doping concentration of Fe.

14. The semiconductor device according to claim 13, further comprising a third GaN layer formed between the second GaN layer and the electron supply layer.

15. The semiconductor device according to claim 14, wherein the third GaN layer is doped with C under constant concentration.

16. The semiconductor device according to claim 12, wherein the electron supply layer has a band gap greater than the second GaN layer.

17. The semiconductor device according to claim 12, wherein the electron supply layer is AlGaN.

18. The semiconductor device according to claim 12, further comprising a source electrode, a drain electrode and a gate electrode are formed on the electron supply layer.
